(19) United States
(12) Patent Application Publication
(10) Pub. No.: US 2024/0324290 A1
(43) Pub. Date: Sep. 26, 2024

(54) STRETCHABLE DISPLAY APPARATUS

(71) Applicant: Samsung Display Co., LTD., Yongin-si (KR)

(72) Inventor: Jinho JU, Yongin-si (KR)

(21) Appl. No.: 18/613,309

(22) Filed: Mar. 22, 2024

(30) Foreign Application Priority Data
Mar. 24, 2023 (KR) 10-2023-0039087
Jun. 15, 2023 (KR) 10-2023-0077007

(51) Int. Cl. H10K 59/121; H10K 59/131; H10K 102/00

(52) U.S. Cl. CPC H10K 59/1213; H10K 59/1216; H10K 59/131; H10K 2102/311

(57) ABSTRACT

A stretchable display apparatus includes a substrate, a circuit layer on the substrate and including first and second subpixel circuits, and a light-emitting layer on the circuit layer and including first and second light-emitting diodes, where the circuit layer includes a plurality of inorganic insulating layers interposed between the substrate and the light-emitting layer, and a first inorganic conductive pattern and a second inorganic conductive pattern interposed between a first inorganic insulating layer and a second inorganic insulating layer, where the plurality of inorganic insulating layers defines an opening passing through the first and second inorganic insulating layers and being in an area between the first subpixel circuit and the second subpixel circuit, and the first inorganic conductive pattern and the second inorganic conductive pattern are disposed between the first subpixel circuit and the second subpixel circuit and respectively disposed on opposite sides of the opening.

This application claims priority to Korean Patent Application No. 10-2023-0039087, filed on Mar. 24, 2023 and Korean Patent Application No. 10-2023-0077007, filed on Jun. 15, 2023, and all the benefits accruing therefrom under 35 U.S.C. § 119, the content of which in their entirety is herein incorporated by reference.

### BACKGROUND

### 1. Field

Embodiments relate to a display apparatus, and more particularly, to a stretchable display apparatus.

### 2. Description of the Related Art

As displays visually showing various electrical signals have been developed, various display apparatuses having excellent characteristics, such as being thin and lightweight, and having relatively low power consumption, have been introduced. For example, flexible display apparatuses which may be bent or rolled have been introduced. Recently, research and development regarding stretchable display apparatuses capable of transforming into various forms have been actively conducted.

### SUMMARY

Embodiments include a structure of a display apparatus, e.g., a stretchable display apparatus.

Additional features will be set forth in part in the description which follows and, in part, will be apparent from the description, or may be learned by practice of the presented embodiments of the disclosure.

An embodiment of the disclosure includes a stretchable display apparatus including a substrate, a circuit layer disposed on the substrate and including a first subpixel circuit and a second subpixel circuit, and a light-emitting layer disposed on the circuit layer and including a first light-emitting diode electrically connected to the first subpixel circuit and a second light-emitting diode electrically connected to the second subpixel circuit, where the circuit layer includes a plurality of inorganic insulating layers interposed between the substrate and the light-emitting layer, and a first inorganic conductive pattern and a second inorganic conductive pattern interposed between a first inorganic insulating layer and a second inorganic insulating layer among the plurality of inorganic insulating layers, where the plurality of inorganic insulating layers defines an opening passing through the first inorganic insulating layer and the second inorganic insulating layer and disposed in an area between the first subpixel circuit and the second subpixel circuit, and the first inorganic conductive pattern and the second inorganic conductive pattern are disposed between the first subpixel circuit and the second subpixel circuit and respectively disposed on opposite sides of the opening.

In an embodiment, each of a lower surface of the first inorganic conductive pattern and a lower surface of the second inorganic conductive pattern may be in direct contact with an upper surface of the first inorganic insulating layer, and each of an upper surface of the first inorganic conductive pattern and an upper surface of the second inorganic conductive pattern may be in direct contact with a lower surface of the second inorganic insulating layer.

In an embodiment, the first inorganic conductive pattern may have a closed-loop shape surrounding an entirety of the first subpixel circuit in a plan view, and the second inorganic conductive pattern may have a closed-loop shape surrounding an entirety of the second subpixel circuit in the plan view.

In an embodiment, each of the closed-loop shape of the first inorganic conductive pattern and the closed-loop shape of the second inorganic conductive pattern may be a polygonal shape or a circular shape.

In an embodiment, the circuit layer may further include an organic insulating layer interposed between the plurality of inorganic insulating layers and the light-emitting layer, and a part of the organic insulating layer may at least partially fill the opening of the plurality of inorganic insulating layers.

In an embodiment, the stretchable display apparatus may further include a first signal line electrically connected to the first subpixel circuit, a second signal line electrically connected to the second subpixel circuit, and a connection signal line connecting the first signal line to the second signal line, where the connection signal line may overlap the opening of the plurality of inorganic insulating layers, the first inorganic conductive pattern, and the second inorganic conductive pattern.

In an embodiment, a first connection point for electrical connection between the first signal line and the connection signal line may be disposed on a side opposite to the opening of the plurality of inorganic insulating layers with respect to the first inorganic conductive pattern disposed between the first connection point and the opening, and a second connection point for electrical connection between the second signal line and the connection signal line may be disposed on a side opposite to the opening of the plurality of inorganic insulating layers with respect to the second inorganic conductive pattern disposed between the second connection point and the opening.

In an embodiment, the stretchable display apparatus may further include a bottom metal layer interposed between the substrate and the first subpixel circuit or between the substrate and the second subpixel circuit, where the connection signal line may be disposed in a same layer as the bottom metal layer and include a same material as a material of the bottom metal layer.

In an embodiment, the opening of the plurality of inorganic insulating layers may extend to an upper surface of the connection signal line.

In an embodiment, the connection signal line may be disposed on the organic insulating layer.

In an embodiment, the connection signal line may have a serpentine shape in a plan view.

An embodiment of the disclosure includes a stretchable display apparatus including a substrate, a circuit layer disposed on the substrate and including a first subpixel circuit and a second subpixel circuit, and a light-emitting layer disposed on the circuit layer and including a first light-emitting diode electrically connected to the first subpixel circuit and a second light-emitting diode electrically connected to the second subpixel circuit, where the circuit layer includes a plurality of inorganic insulating layers interposed between the substrate and the light-emitting layer, a first inorganic conductive pattern surrounding the first subpixel circuit in a plan view, and a second inorganic conductive pattern disposed adjacent to the first inorganic conductive pattern and surrounding the second subpixel circuit in a plan view.

In an embodiment, the plurality of inorganic insulating layers may include a first inorganic insulating layer and a second inorganic insulating layer, each of a lower surface of the first inorganic conductive pattern and a lower surface of the second inorganic conductive pattern may be in direct contact with an upper surface of the first inorganic insulating layer, and each of an upper surface of the first inorganic conductive pattern and an upper surface of the second inorganic conductive pattern may be in direct contact with a lower surface of the second inorganic insulating layer.

In an embodiment, the plurality of inorganic insulating layers may have a mesh structure in the plan view and define an opening at least partially filled with an organic insulating material, and a part of the opening may be disposed in an area between the first inorganic conductive pattern and the second inorganic conductive pattern.

In an embodiment, the stretchable display apparatus may further include a first signal line electrically connected to the first subpixel circuit, a second signal line electrically connected to the second subpixel circuit, and a connection signal line connecting the first signal line to the second signal line, where the connection signal line may overlap the opening of the plurality of inorganic insulating layers, the first inorganic conductive pattern, and the second inorganic conductive pattern.

In an embodiment, a first connection point for electrical connection between the first signal line and the connection signal line may be disposed on a side opposite to the opening of the plurality of inorganic insulating layers with respect to the first inorganic conductive pattern disposed between the first connection point and the opening, and a second connection point for electrical connection between the second signal line and the connection signal line may be disposed on a side opposite to the opening of the plurality of inorganic insulating layers with respect to the second inorganic conductive pattern disposed between the second connection point and the opening.

In an embodiment, the stretchable display apparatus may further include a bottom metal layer interposed between the substrate and the first subpixel circuit or between the substrate and the second subpixel circuit, where the connection signal line may be disposed in a same layer as the bottom metal layer and include a same material as a material of the bottom metal layer.

In an embodiment, the opening of the plurality of inorganic insulating layers may extend to an upper surface of the connection signal line.

In an embodiment, the stretchable display apparatus may further include an organic insulating layer including the organic insulating material, where the connection signal line may be disposed on the organic insulating layer.

In an embodiment, the connection signal line may have a serpentine shape in the plan view.

### BRIEF DESCRIPTION OF THE DRAWINGS

The above and other features and advantages of illustrative embodiments of the disclosure will be more apparent from the following description taken in conjunction with the accompanying drawings, in which:

FIG. 1 is a perspective view schematically illustrating an embodiment of a stretchable display apparatus (hereinafter, also referred to as a “display apparatus”);

FIG. 2A is a perspective view illustrating an embodiment of a first state in which a display apparatus is tensioned in a first direction;

FIG. 2B is a perspective view illustrating an embodiment of a second state in which the display apparatus is tensioned in a second direction;

FIG. 3 is an equivalent circuit diagram schematically illustrating an embodiment of at least one light-emitting diode (LED) of the display apparatus and a subpixel circuit PC electrically connected to the LED;

FIG. 4 is a plan view illustrating an embodiment of a part of the display apparatus;

FIG. 5 is a cross-sectional view of an embodiment of the display apparatus, taken along line V-V′ of FIG. 4;

FIG. 6 is a cross-sectional view of an embodiment of the display apparatus, taken along line V-V′ of FIG. 4;

FIG. 7 is a plan view schematically illustrating an embodiment of a part of a display apparatus; and

FIG. 8 is a cross-sectional view of an embodiment of the display apparatus, taken along line V-V′ of FIG. 4.

### DETAILED DESCRIPTION

Reference will now be made in detail to embodiments, embodiments of which are illustrated in the accompanying drawings, where like reference numerals refer to like elements throughout. In this regard, the illustrated embodiments may have different forms and should not be construed as being limited to the descriptions set forth herein. Accordingly, the embodiments are merely described below, by referring to the drawing figures, to explain features of the description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As embodiments allow for various changes and numerous embodiments, embodiments will be illustrated in the drawings and described in detail in the written description. The effects, features of the disclosure and methods for achieving the same may be clarified by referring to the following detailed embodiments along with the drawings. The disclosure may, however, be embodied in many different forms and should not be construed as limited to the embodiments set forth herein.

Hereinafter, embodiments of the disclosure are explained in detail referring to the attached drawings. When referring to the drawings, like reference numerals may denote like or corresponding elements, and repeated descriptions thereof are omitted.

It will be understood that although the terms “first,” “second,” etc. may be used herein to describe various components, these components should not be limited by these terms. These components are only used to distinguish one component from another.

As used herein, the singular forms “a,” “an” and “the” are intended to include the plural forms as well, unless the context clearly indicates otherwise.

It will be further understood that the terms “comprises” and/or “comprising” used herein specify the presence of stated features or components, but do not preclude the presence or addition of one or more other features or components.

It will be understood that when a layer, region, or component is also referred to as being “on” another layer, region, or component, it may be “directly on” the other layer, region, or component or may be “indirectly on” the other layer, region, or component with one or more intervening layers, regions, or components therebetween.

Sizes of components in the drawings may be exaggerated for convenience of explanation. In other words, since sizes and thicknesses of components in the drawings are arbitrarily illustrated for convenience of explanation, the disclosure is not limited thereto.

When an illustrative embodiment may be implemented differently, a predetermined process order may be performed differently from the described order. In an embodiment, two consecutively described processes may be performed substantially at the same time or performed in an order opposite to the described order.

In the disclosure, “A and/or B” may include “A,” “B,” or “A and B.” In addition, in the disclosure, “at least one of A and B” may include “A,” “B,” or “A and B.”

It will be understood that when a layer, region, or component is also referred to as being connected to another layer, region, or component, it may be directly or indirectly connected to the other layer, region, or component. That is, e.g., intervening layers, regions, or components may be present. In an embodiment, it will be understood that when a layer, region, or component is also referred to as being “electrically connected to” another layer, region, or component, it may be “directly electrically connected to” the other layer, region, or component or may be “indirectly electrically connected to” the other layer, region, or component with one or more intervening layers, regions, or components therebetween.

In the disclosure, the x-axis, the y-axis and the z-axis are not limited to three axes of the quadrangular, e.g., rectangular coordinate system, and may be interpreted in a broader sense. In an embodiment, the x-axis, the y-axis, and the z-axis may be perpendicular to one another, or may represent different directions that are not perpendicular to one another.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term such as “about” can mean within one or more standard deviations, or within +30%, 20%, 10%, 5% of the stated value, for example.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

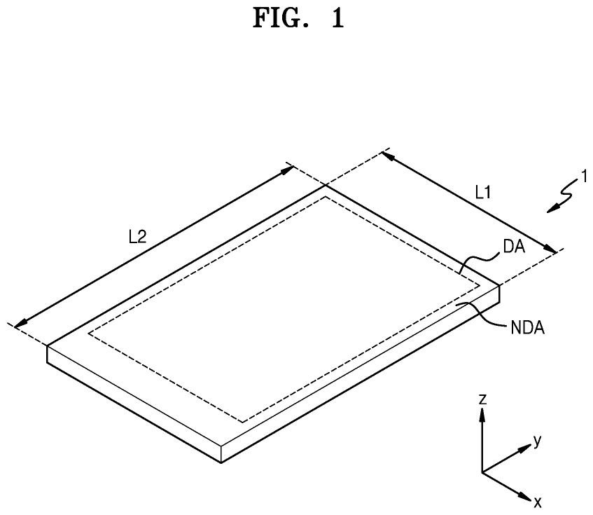

FIG. 1 is a perspective view schematically illustrating an embodiment of a stretchable display apparatus 1 (hereinafter, also referred to as a “display apparatus”).

Referring to FIG. 1, the display apparatus 1 may include a display area DA and a non-display area NDA. The display area DA may include a plurality of subpixels. The display apparatus 1 may provide a predetermined image by light emitted from the plurality of subpixels. The non-display area NDA may be adjacent to the display area DA. In an embodiment, the non-display area NDA may surround an entirety of the display area DA.

The display apparatus 1 may include a first side L1 extending in a first direction and a second side L2 extending in a second direction. Each of the first side L1 and the second side L2 may be an edge of the display apparatus 1. The first direction and the second direction may intersect each other. In an embodiment, the first direction and the second direction may form an acute angle. In another embodiment, the first direction and the second direction may form an obtuse angle or cross at right angles. Hereinafter, embodiments are described focusing on the case where the first direction is the x direction or the −x direction, and the second direction is the y direction or the −y direction. FIG. 1 illustrates the display apparatus 1 of which the first side L1 is shorter than the second side L2; however, in another embodiment, the first side L1 may be greater than the second side L2.

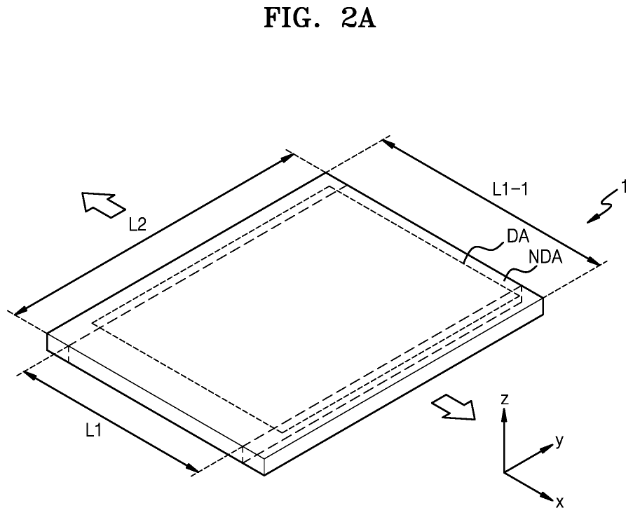

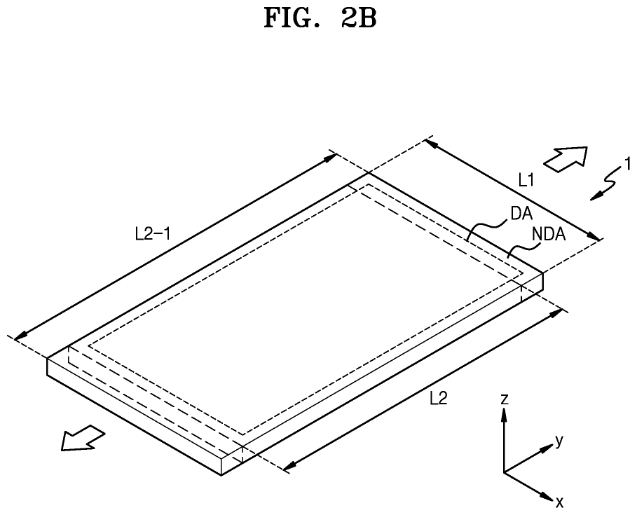

FIG. 2A is a perspective view illustrating an embodiment of a first state in which the display apparatus 1 is tensioned in the first direction, and FIG. 2B is a perspective view illustrating an embodiment of a second state in which the display apparatus 1 is tensioned in the second direction.

As illustrated in FIG. 2A, the display apparatus 1 may be tensioned in the first direction (i.e., x direction or −x direction) when external force (e.g., tensile force) is applied thereto in the first direction (i.e., x direction or −x direction). In this case, a first side L1-1 may be longer than the first side L1 in FIG. 2A which represents the first side before the external force is applied. Each of the display area DA and the non-display area NDA may be tensioned in the first direction (e.g., x direction or −x direction).

In another embodiment, the display apparatus 1 may be contracted in the first direction (i.e., x direction or −x direction) when external force (e.g., contractile force) is applied to the display apparatus 1 in the first direction (i.e., x direction or −x direction). In this case, a first side L1-1 of FIG. 2A may be shorter than the first side L1 in FIG. 2A which represents the first side before the external force is applied. Each of the display area DA and the non-display area NDA may be contracted in the first direction (e.g., x direction or −x direction).

Referring to FIG. 2B, the display apparatus 1 may be tensioned in the second direction (i.e., y direction or −y direction) when external force (e.g., tensile force) is applied to the display apparatus 1 in the second direction (i.e., y direction or −y direction). In this case, a second side L2-1 of FIG. 2B may be longer than the second side L2 in FIG. 2B which represents the second side before the external force is applied. Each of the display area DA and the non-display area NDA may be tensioned in the second direction (e.g., y direction or −y direction).

In another embodiment, the display apparatus 1 may be contracted in the second direction (i.e., y direction or −y direction) when external force (e.g., contractile force) is applied to the display apparatus 1 in the second direction (i.e., y direction or −y direction). In this case, the second side L2-1 of FIG. 2B may be shorter than the second side L2 in FIG. 2B which represents the second side before the external force is applied. Each of the display area DA and the non-display area NDA may be contracted in the second direction (e.g., y direction or −y direction). As such, when the tensile force or the contractile force is applied to the display apparatus 1, the display apparatus 1 may be transformed into various shapes.

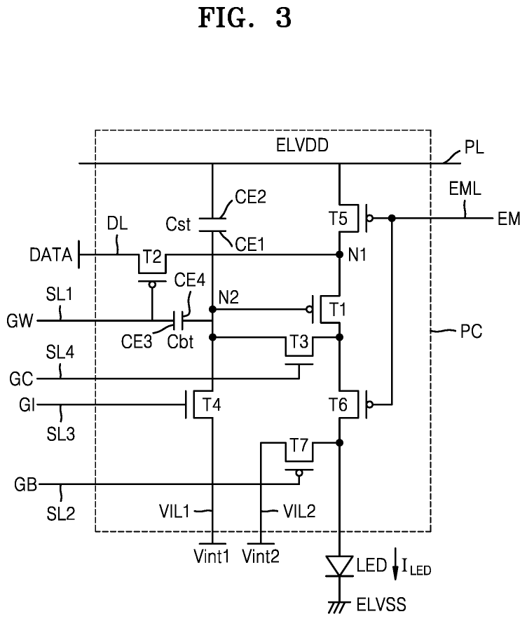

FIG. 3 is an equivalent circuit diagram schematically illustrating an embodiment of at least one light-emitting diode LED of the display apparatus 1 and a subpixel circuit PC electrically connected to the light-emitting diode LED.

Referring to FIG. 3, the light-emitting diode LED may be electrically connected to the subpixel circuit PC including a plurality of transistors, a storage capacitor and a boosting capacitor.

The light-emitting diode LED may be an organic light-emitting diode including an organic material as a luminous material. In another embodiment, the light-emitting diode LED may be an inorganic light-emitting diode including an inorganic material. The inorganic light-emitting diode may include a PN junction diode including inorganic semiconductor-based materials. When a voltage is applied in a forward direction to a PN junction diode, holes and electrons are injected, and energy generated due to recombination of the holes and the electrons may be converted into light energy to emit light of a predetermined color. The aforementioned inorganic light-emitting diode may have a width of several to hundreds of micrometers or several to hundreds of nanometers. In an embodiment, the light-emitting diode LED may include a quantum-dot light-emitting diode. As described above, a light-emitting layer of the light-emitting diode LED may include an organic material, an inorganic material, quantum dots, an organic material with quantum dots, or an inorganic material with quantum dots. Hereinafter, for the sake of convenience, the case in which the light-emitting diode LED is an organic light-emitting diode is described.

The subpixel circuit PC may include a first transistor T1, a second transistor T2, a third transistor T3, a fourth transistor T4, a fifth transistor T5, a sixth transistor T6, a seventh transistor T7, a first capacitor Cst, and a second capacitor Cbt.

The subpixel circuit PC may include signal lines, a first initialization voltage line VIL1, a second initialization voltage line VIL2, and a driving voltage line PL. The signal lines may include a data line DL, a first scan line SL1, a second scan line SL2, a third scan line SL3, a fourth scan line SL4, and an emission control line EML. In another embodiment, at least one of the signal lines, the first and second initialization voltage lines VIL1 and VIL2, and/or the driving voltage line PL may be shared by neighboring subpixel circuits.

The driving voltage line PL may transmit a first power voltage ELVDD to the first transistor T1. The first initialization voltage line VIL1 may transmit a first initialization voltage Vint1 initializing the first transistor T1 to the subpixel circuit PC. The second initialization voltage line VIL2 may transmit a second initialization voltage Vint2 initializing the light-emitting diode LED to the subpixel circuit PC.

The first transistor T1 may be connected to the driving voltage line PL via the fifth transistor T5, and may be electrically connected to the light-emitting diode LED via the sixth transistor T6. The first transistor T1 may function as a driver transistor and may provide a driving current ILED to the light-emitting diode LED by receiving a data signal DATA according to a switching operation of the second transistor T2.

The second transistor T2, as a switching transistor, may be connected to the first scan line SL1 and the data line DL and may be connected to the driving voltage line PL via the fifth transistor T5. The second transistor T2 may be turned on according to a first scan signal GW received through the first scan line SL1 and perform a switching operation to transmit to a first node N1 the data signal DATA transmitted through the data line DL.

The third transistor T3, as a compensation transistor, may be connected to the fourth scan line SL4 and may be connected to the light-emitting diode LED via the sixth transistor T6. The third transistor T3 may be turned on according to a fourth scan signal GC transmitted through the fourth scan line SL4 and diode-connect the first transistor T1.

The fourth transistor T4, as a first initialization transistor, may be connected to the third scan line SL3, which is a previous scan line, and the first initialization voltage line VIL1, and may be turned on according to a third scan signal GI, which is a previous scan signal received through the third scan line SL3 to transmit the first initialization voltage Vint1 from the first initialization voltage line VIL1 to a gate electrode of the first transistor T1, resulting in initialization of voltage of the gate electrode of the first transistor T1.

The fifth transistor T5 may be an operation control transistor, and the sixth transistor T6 may be an emission control transistor. The fifth transistor T5 and the sixth transistor T6 may be connected to the emission control line EML and may be simultaneously turned on according to an emission control signal EM received through the emission control line EML to form a current path such that a driving current ILED flows in a direction of the light-emitting diode LED from the driving voltage line PL.

The seventh transistor T7, as a second initialization transistor, may be electrically connected to the second scan line SL2, the second initialization voltage line VIL2, and the sixth transistor T6. The seventh transistor T7 may be turned on according to a second scan signal GB received through the second scan line SL2 and transmit the second initialization voltage Vint2 from the second initialization voltage line VIL2 to the light-emitting diode LED to initialize the light-emitting diode LED. The seventh transistor T7 may be omitted. The second scan signal GB of the second scan line SL2 may be a scan signal of a first scan line arranged in a previous row of the subpixel circuit PC.

A first capacitor Cst may include a first electrode CE1 and a second electrode CE2. The first electrode CE1 may be connected to a gate electrode of the first transistor T1, and the second electrode CE2 may be connected to the driving voltage line PL. The first capacitor Cst, as a storage capacitor, may store and maintain a voltage corresponding to a voltage difference between an end of the driving voltage line PL and an end of the gate electrode of the first transistor T1 to maintain a voltage applied to the gate electrode of the first transistor T1.

A second capacitor Cbt may include a third electrode CE3 and a fourth electrode CE4. The third electrode CE3 may be connected to the first scan line SL1 and a gate electrode of the second transistor T2. The fourth electrode CE4 may be connected to the gate electrode of the first transistor T1 and the first electrode CE1 of the first capacitor Cst. The second capacitor Cbt, as a boosting capacitor, may reduce a voltage (black voltage) indicating black by increasing a voltage of a second node N2 when a first scan signal GW of the first scan line SL1 is a voltage turning off the second transistor T2.

The light-emitting diode LED may include a first electrode (e.g., anode), and a second electrode (e.g., cathode), which face each other, and a light-emitting layer between the first electrode and the second electrode. A second power voltage ELVSS may be applied to the second electrode. The light-emitting layer of the light-emitting diode LED may receive the driving current ILED from the first transistor T1 and emit light.

Specific operations of the subpixel circuit PC in an embodiment are described below.

During a first initialization period, when the third scan signal GI is provided through the third scan line SL3, the fourth transistor T4 may be turned on in response to the third scan signal GI, and the first transistor T1 may be initialized by the first initialization voltage Vint1 provided from the first initialization voltage line VIL1.

During a data programming period, when the first scan signal GW and the fourth scan signal GC are provided through the first scan line SL1 and the fourth scan line SL4, respectively, the second transistor T2 and the third transistor T3 may be turned on in response to the first scan signal GW and the fourth scan signal GC, respectively. At this time, the first transistor T1 may be diode-connected by the turned-on third transistor T3 and may be biased in the forward direction. Then, a voltage, in which a threshold voltage of the first transistor T1 is compensated for from a data signal DATA supplied from the data line DL, is applied to the gate electrode of the first transistor T1. The first power voltage ELVDD and compensated voltage may be respectively applied to two opposite ends of the first capacitor Cst, and a charge corresponding to a voltage difference between the two opposite ends may be stored in the first capacitor Cst.

During an emission period, the fifth transistor T5 and the sixth transistor T6 may be turned-on by the emission control signal EM provided from the emission control line EML. The driving current ILED according to the voltage difference between the voltage of the gate electrode of the first transistor T1 and the first power voltage ELVDD may be generated, and the driving current ILED may be provided to the light-emitting diode LED through the sixth transistor T6.

During a second initialization period, when the second scan signal GB is provided through the second scan line SL2, the seventh transistor T7 may be turned on in response to the second scan signal GB, and the light-emitting diode LED may be initialized by the second initialization voltage Vint2 provided from the second initialization voltage line VIL2.

At least one of the first to seventh transistors T1 to T7 of the subpixel circuit PC may include a semiconductor layer including an oxide, and the rest of the transistors may include a semiconductor layer including silicon. FIG. 3 illustrates that the third transistor T3 and the fourth transistor T4 are an oxide-based transistor and are implemented as an n-channel metal-oxide-semiconductor (“NMOS”) transistor, and that the first transistor T1, the second transistor T2, the fifth transistor T5, the sixth transistor T6, and the seventh transistor T7 are a silicon-based transistor and are implemented as a p-channel metal-oxide-semiconductor (“PMOS”) transistor. In another embodiment, the third transistor T3 may be implemented as an NMOS transistor, and the first transistor T1, the second transistor T2, the fourth transistor T4, the fifth transistor T5, the sixth transistor T6, and the seventh transistor T7 may be implemented by a PMOS transistor.

More specifically, the first transistor T1 directly influencing the brightness of a display apparatus may include a semiconductor layer including polycrystalline silicon having a relatively high reliability, and through this, a high-resolution display apparatus may be implemented.

In addition, since an oxide-based semiconductor has a relatively high carrier mobility and a relatively small leakage current, a voltage drop may not be relatively large even when a driving time is long. That is, even during a low-frequency driving, a color change of an image depending on a voltage drop may not be relatively large and thus a display apparatus may be driven at relatively low frequencies. As such, since an oxide-based semiconductor has an advantage that a leakage current is small, by forming a semiconductor layer of at least one of the third transistor T3 and the fourth transistor T4 each connected to the gate electrode of the first transistor T1 using an oxide-based semiconductor, a leakage current that may flow to the gate electrode of the first transistor T1 may be prevented and simultaneously, the power consumption may be reduced.

The subpixel circuit PC is not limited to the number of transistors, the number of capacitors, and a circuit design described with reference to FIG. 3, and the number and circuit design of the subpixel circuit PC may be variously changed.

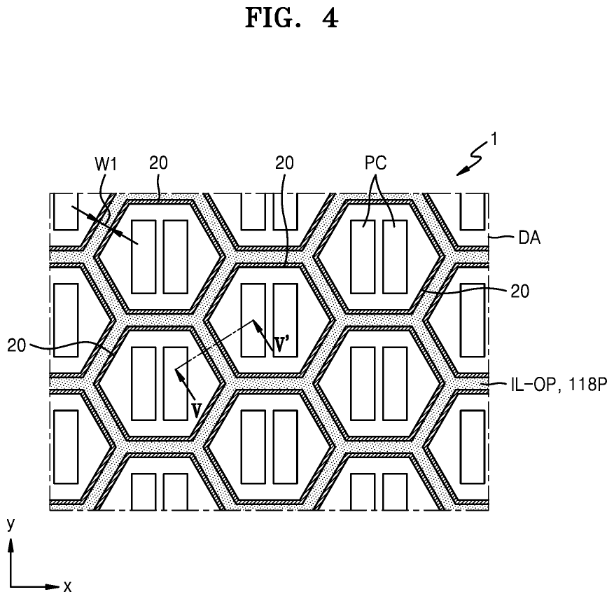

FIG. 4 is a plan view illustrating an embodiment of a part of the display apparatus 1.

Referring to FIG. 4, the display apparatus 1 may include a plurality of subpixel circuits PC arranged in the display area DA. Each of the plurality of subpixel circuits PC may include transistors and capacitors as described above in relation to FIG. 3.

The display apparatus 1 may include a plurality of conductive inorganic structures 20 arranged in the display area DA. Each of the plurality of conductive inorganic structures 20 may have a closed loop shape in a plan view. In an embodiment, FIG. 4 illustrates that each of the plurality of conductive inorganic structures 20 has a hexagonal shape; however, the disclosure is not limited thereto. In another embodiment, each of the plurality of conductive inorganic structures 20 may have a polygonal (n-polygon where n is a natural number greater than or equal to 3) or circular shape.

Each of the plurality of conductive inorganic structures 20 may surround the subpixel circuit PC in a plan view. In an embodiment, FIG. 4 illustrates that each of the plurality of conductive inorganic structures 20 surrounds two subpixel circuits PC. In another embodiment, each of the plurality of conductive inorganic structures 20 may surround one or three or more subpixel circuits PC.

The conductive inorganic structures 20 may be spaced apart from each other, and an organic insulating material 118P may be arranged between neighboring conductive inorganic structures 20. The organic insulating material 118P may have a mesh structure in a plan view as illustrated in FIG. 4. The organic insulating material 118P having a mesh structure may surround each of the plurality of conductive inorganic structures 20 in a plan view. In other words, a part of the organic insulating material 118P may be disposed between neighboring conductive inorganic structures 20.

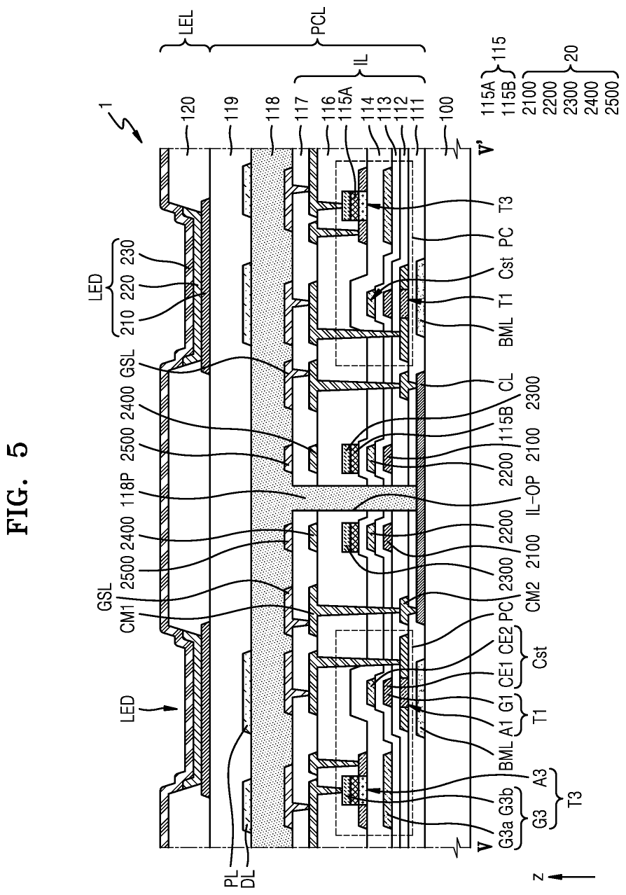

The organic insulating material 118P may be defined by inorganic insulating layers IL (refer to FIG. 5) to be described below with reference to FIG. 5 and may be in an opening IL-OP. The opening IL-OP may have a first width W1. In an embodiment, the first width W1 may be measured in a direction perpendicular to a main extension direction of the opening IL-OP. The description such as “the organic insulating material 118P is described as having a mesh structure” denotes that the opening IL-OP defined by the inorganic insulating layers IL (refer to FIG. 5) to be described later may have a mesh structure. In addition, when the opening IL-OP is described as having the first width W1, it means that the organic insulating material 118P in the opening IL-OP may have the first width W1.

The opening IL-OP defined by the inorganic insulating layers IL (refer to FIG. 5) having a mesh structure may surround each of the plurality of conductive inorganic structures 20 in a plan view. In other words, a part of the opening IL-OP defined by the inorganic insulating layers IL (refer to FIG. 5) may be disposed between neighboring conductive inorganic structures 20.

FIG. 5 is a cross-sectional view of an embodiment of the display apparatus 1, taken along line V-V′ of FIG. 4.

Referring to FIG. 5, the display apparatus 1 may include a substrate 100, a circuit layer PCL on the substrate 100, and a light-emitting layer LEL on the circuit layer PCL. The substrate 100, may include an organic insulating material such as a polymer resin. The substrate 100 may include a polymer resin such as polyethersulfone, polyarylate, polyether imide, polyethylene naphthalate, polyethylene terephthalate, polyphenylene sulfide, polyimide, polycarbonate, cellulose triacetate, or cellulose acetate propionate. In an embodiment, the substrate 100 may have a multi-layer structure including a base layer including the aforementioned polymer resin and a barrier layer including an inorganic insulating material. The substrate 100 including a polymer resin may be flexible, rollable, or bendable.

The circuit layer PCL may include a plurality of subpixel circuits PC. The subpixel circuit PC may include a plurality of transistors as described above with reference to FIG. 3. In this regard, FIG. 5 illustrates the first transistor T1 and the third transistor T3 as well as the first capacitor Cst which are included in the subpixel circuit PC.

The first transistor T1 may include a first semiconductor layer A1 and a first gate electrode G1 partially overlapping the first semiconductor layer A1. The first semiconductor layer A1 may be disposed on the substrate 100 with a buffer layer 111 arranged therebetween. The first semiconductor layer A1 may be a silicon-based semiconductor layer. A first gate insulating layer 112 may be disposed on the first semiconductor layer A1 and the buffer layer 111. The first gate insulating layer 112 may be an inorganic insulating layer including an inorganic insulating material such as a silicon oxide, a silicon nitride, and/or a silicon oxynitride, and may have a single-layer or multi-layer structure including the aforementioned material.

The first gate electrode G1 and the first electrode CE1 of the first capacitor Cst may be disposed on the first gate insulating layer 112. FIG. 5 illustrates that the first gate electrode G1 is integrated with the first electrode CE1 of the first capacitor Cst. In other words, the first gate electrode G1 may perform the function of the first electrode CE1 of the first capacitor Cst, or the first electrode CE1 of the first capacitor Cst may perform the function of the first gate electrode G1.

The first gate electrode G1 and/or the first electrode CE1 of the first capacitor Cst may include aluminum (Al), platinum (Pt), palladium (Pd), silver (Ag), magnesium (Mg), gold (Au), nickel (Ni), neodymium (Nd), iridium (Ir), chrome (Cr), lithium (Li), calcium (Ca), molybdenum (Mo), titanium (Ti), tungsten (W), and/or copper (Cu) and have a single-layer or multi-layer structure including the aforementioned material.

A first inter-insulating layer 113 may be disposed on the first gate electrode G1 and/or the first electrode CE1 of the first capacitor Cst and the first gate insulating layer 112. The first inter-insulating layer 113 may be an inorganic insulating layer including an inorganic insulating material such as a silicon oxide, a silicon nitride, and/or a silicon oxynitride, and may have a single-layer or multi-layer structure including the aforementioned material.

The second electrode CE2 of the first capacitor Cst may be disposed on the first inter-insulating layer 113. The second electrode CE2 of the first capacitor Cst may include aluminum (Al), platinum (Pt), palladium (Pd), silver (Ag), magnesium (Mg), gold (Au), nickel (Ni), neodymium (Nd), iridium (Ir), chrome (Cr), lithium (Li), calcium (Ca), molybdenum (Mo), titanium (Ti), tungsten (W), and/or copper (Cu) and may have a single-layer or multi-layer structure including the aforementioned material. The second electrode CE2 of the first capacitor Cst may overlap the first gate electrode G1 and/or the first electrode CE1 of the first capacitor Cst.

A second inter-insulating layer 114 may be disposed on the second electrode CE2 of the first capacitor Cst and the first inter-insulating layer 113. The second inter-insulating layer 114 may be an inorganic insulating layer including an inorganic insulating material such as a silicon oxide, a silicon nitride, and/or a silicon oxynitride, and may have a single-layer or multi-layer structure including the aforementioned material.

A third semiconductor layer A3 of the third transistor T3 may be disposed on the second inter-insulating layer 114. The third semiconductor layer A3 may be an oxide-based semiconductor layer. A third gate electrode G3 may be arranged under and/or on the third semiconductor layer A3. In an embodiment, FIG. 5 illustrates that the third gate electrode G3 includes a third lower gate electrode G3a arranged under the third semiconductor layer A3 and a third upper gate electrode G3b disposed on the third semiconductor layer A3. In another embodiment, any one of the third lower gate electrode G3a and the third upper gate electrode G3b may be omitted.

The third lower gate electrode G3a may include the same material as that of the second electrode CE2 of the first capacitor Cst, and may be disposed on the same layer (e.g., the first inter-insulating layer 113). That is, the third lower gate electrode G3a may be disposed in the same layer as the second electrode CE2. The third upper gate electrode G3b may be disposed on the third semiconductor layer A3 with a first portion 115A of a second gate insulating layer 115 arranged therebetween. The third upper gate electrode G3b may include aluminum (Al), platinum (Pt), palladium (Pd), silver (Ag), magnesium (Mg), gold (Au), nickel (Ni), neodymium (Nd), iridium (Ir), chrome (Cr), lithium (Li), calcium (Ca), molybdenum (Mo), titanium (Ti), tungsten (W), and/or copper (Cu) and may have a single-layer or multi-layer structure including the aforementioned material.

FIG. 5 illustrates that the first portion 115A of the second gate insulating layer 115 has the same pattern as each of the third upper gate electrode G3b and a channel region of the third semiconductor layer A3; however, the disclosure is not limited thereto. The first portion 115A of the second gate insulating layer 115 may be connected to a second portion 115B of the second gate insulating layer 115 to be described below in an integrated manner. The second gate insulating layer 115, e.g., the first portion 115A and the second portion 115B of the second gate insulating layer 115 may be an inorganic insulating layer including an inorganic insulating material such as a silicon oxide, a silicon nitride, and/or a silicon oxynitride, and may have a single-layer or multi-layer structure including the aforementioned material.

A third inter-insulating layer 116 may be disposed on the third upper gate electrode G3b and the second inter-insulating layer 114. The third inter-insulating layer 116 may be an inorganic insulating layer including an inorganic insulating material such as a silicon oxide, a silicon nitride, and/or a silicon oxynitride, and may have a single-layer or multi-layer structure including the aforementioned material.

A fourth inter-insulating layer 117 may be disposed on the third inter-insulating layer 116. The fourth inter-insulating layer 117 may be an inorganic insulating layer including an inorganic insulating material such as a silicon oxide, a silicon nitride, and/or a silicon oxynitride, and may have a single-layer or multi-layer structure including the aforementioned material.

The data line DL and the driving voltage line PL may be disposed on a first organic insulating layer 118 disposed on the fourth inter-insulating layer 117. The first organic insulating layer 118 may include an organic insulating material such as benzocyclobutene (“BCB”), polyimide, or hexamethyldisiloxane (“HMDSO”).

The data line DL and the driving voltage line PL may include at least one material selected from among aluminum (Al), platinum (Pt), palladium (Pd), silver (Ag), magnesium (Mg), gold (Au), nickel (Ni), neodymium (Nd), iridium (Ir), chrome (Cr), lithium (Li), calcium (Ca), molybdenum (Mo), titanium (Ti), tungsten (W), and copper (Cu). In an embodiment, the data line DL and the driving voltage line PL may each have a triple-layer structure in which a titanium layer, an aluminum layer, and a titanium layer are stacked, for example.

A second organic insulating layer 119 may be disposed on the data line DL, the driving voltage line PL and the first organic insulating layer 118. The second organic insulating layer 119 may include an organic insulating material such as benzocyclobutene (“BCB”), polyimide, or hexamethyldisiloxane (“HMDSO”).

The light-emitting layer LEL may include a plurality of light-emitting diodes LED electrically connected to the subpixel circuits PC. The light-emitting diode LED may be formed on the second organic insulating layer 119. The light-emitting diode LED may include a first electrode 210, a light-emitting layer 220, and a second electrode 230 on the second organic insulating layer 119. In an embodiment, the light-emitting layer 220 may include a relatively low molecular weight organic material or a relatively high molecular weight organic material. At least one layer selected from among a hole injection layer (“HIL”), a hole transport layer (“HTL”), an electron transport layer (“ETL”), and an electron injection layer (“EIL”) may be further arranged between the first electrode 210 and the second electrode 230.

An edge of the first electrode 210 may be covered by a bank layer 120, and an inner portion (or central portion) of the first electrode 210 may overlap the light-emitting layer 220 through an opening of the bank layer 120. The second electrode 230 may be formed in correspondence with the plurality of light-emitting diodes LED whereas the first electrode 210 may be formed separately with respect to the light-emitting diodes LED. In other words, the plurality of light-emitting diodes LED may share the second electrode 230, and the stacked structure of the first electrode 210, the light-emitting layer 220, and a part of the second electrode 230 may be the light-emitting diode LED. The light-emitting diode LED may be sealed by an encapsulation layer including an inorganic encapsulation layer and an organic encapsulation layer.

The inorganic insulating layer IL included in the circuit layer PCL may define the opening IL-OP. The inorganic insulating layer IL may include the buffer layer 111, the first gate insulating layer 112, the first inter-insulating layer 113, the second inter-insulating layer 114, the second gate insulating layer 115, the third inter-insulating layer 116, and the fourth inter-insulating layer 117 as illustrated in FIG. 5. The opening IL-OP may pass through at least one inorganic insulating layer from a plurality of inorganic insulating layers included in the inorganic insulating layer IL. The opening IL-OP of the inorganic insulating layer IL may pass through the buffer layer 111, the first gate insulating layer 112, the first inter-insulating layer 113, the second inter-insulating layer 114, the second gate insulating layer 115, the third inter-insulating layer 116, and the fourth inter-insulating layer 117 as illustrated in FIG. 5. The opening IL-OP may be at least partially filled with the organic insulating material 118P which is a part of the first organic insulating layer 118. As the organic insulating material 118P is in the opening IL-OP of the inorganic insulating layer IL, when the disclosure describes “A and B may be disposed on opposite sides of the opening IL-OP of the inorganic insulating layer IL,” it may denote “A and B may be respectively disposed on opposite sides of the organic insulating material 118P.”

The conductive inorganic structures 20 may be disposed on opposite sides of the opening IL-OP of the inorganic insulating layer IL. In an embodiment, the conductive inorganic structures 20 may be disposed on both left side and right side of the opening IL-OP of the inorganic insulating layer IL, for example.

Each of the conductive inorganic structures 20 may include an inorganic conductive pattern interposed between two inorganic insulating layers which are adjacent to each other in the vertical direction (e.g., z direction or the depth direction of the opening IL-OP) among a plurality of inorganic insulating layers IL. In an embodiment, FIG. 5 illustrates that each of the conductive inorganic structures 20 include a first inorganic conductive pattern (also referred to as a first inorganic conductive layer) 2100, a second inorganic conductive pattern (also referred to as a second inorganic conductive layer) 2200, a third inorganic conductive pattern (also referred to as a third inorganic conductive layer) 2300, a fourth inorganic conductive pattern (also referred to as a fourth inorganic conductive layer) 2400, and a fifth inorganic conductive pattern (also referred to as a fifth inorganic conductive layer) 2500; however, the disclosure is not limited thereto. In another embodiment, each of the conductive inorganic structures 20 may include at least one inorganic conductive pattern selected from the first to fifth inorganic conductive patterns 2100, 2200, 2300, 2400, and 2500. In an alternative embodiment, each of the conductive inorganic structures 20 may include two, three, or four inorganic conductive patterns selected from the first to fifth inorganic conductive patterns 2100, 2200, 2300, 2400, and 2500.

Two adjacent first inorganic conductive layers 2100 may be arranged between two adjacent subpixel circuits PC, and may be respectively placed on opposite sides of the opening IL-OP of the inorganic insulating layer IL. The first inorganic conductive layer 2100 disposed on the left side of the opening IL-OP of the inorganic insulating layer IL and the first inorganic conductive layer 2100 disposed on the right side of the opening IL-OP of the inorganic insulating layer IL may include the same material and be disposed on the same layer (e.g., the first gate insulating layer 112). That is, the first inorganic conductive layer 2100 disposed on the left side of the opening IL-OP may be disposed on the same layer as the first inorganic conductive layer 2100 disposed on the right side of the opening IL-OP. In an embodiment, each first inorganic conductive layer 2100 may include the same materials as the first gate electrode G1 and the first electrode CE1 of the first capacitor Cst, for example.

A lower surface of the first inorganic conductive layer 2100 may be in direct contact with an upper surface of the first gate insulating layer 112, and an upper surface of the first inorganic conductive layer 2100 may be in direct contact with a lower surface of the first inter-insulating layer 113. In an embodiment, the entirety of the lower surface of the first inorganic conductive layer 2100 may be in direct contact with the upper surface of the first gate insulating layer 112, and the entirety of the upper surface of the first inorganic conductive layer 2100 may be in direct contact with the lower surface of the first inter-insulating layer 113, for example.

Two adjacent second inorganic conductive layers 2200 may be arranged between two adjacent subpixel circuits PC, and may be respectively placed on opposite sides of the opening IL-OP of the inorganic insulating layer IL. The second inorganic conductive layer 2200 disposed on the left side of the opening IL-OP of the inorganic insulating layer IL and the second inorganic conductive layer 2200 disposed on the right side of the opening IL-OP of the inorganic insulating layer IL may include the same material and be disposed on the same layer (e.g., the first inter-insulating layer 113). That is, the second inorganic conductive layer 2200 disposed on the left side of the opening IL-OP may be disposed in the same layer as the second inorganic conductive layer 2200 disposed on the right side of the opening IL-OP. In an embodiment, each second inorganic conductive layer 2200 may include the same material as that of the second electrode CE2 of the first capacitor Cst, for example.

A lower surface of the second inorganic conductive layer 2200 may be in direct contact with an upper surface of the first inter-insulating layer 113, and an upper surface of the second inorganic conductive layer 2200 may be in direct contact with a lower surface of the second inter-insulating layer 114. In an embodiment, the entirety of the lower surface of the second inorganic conductive layer 2200 may be in direct contact with the upper surface of the first inter-insulating layer 113, and the entirety of the upper surface of the second inorganic conductive layer 2200 may be in direct contact with the lower surface of the second inter-insulating layer 114, for example.

Two adjacent third inorganic conductive layers 2300 may be arranged between two adjacent subpixel circuits PC, and may be respectively placed on opposite sides of the opening IL-OP of the inorganic insulating layer IL. The third inorganic conductive layer 2300 disposed on the left side of the opening IL-OP of the inorganic insulating layer IL and the third inorganic conductive layer 2300 disposed on the right side of the opening IL-OP of the inorganic insulating layer IL may include the same material. In an embodiment, each third inorganic conductive layer 2300 may include the same material as that of the third upper gate electrode G3b of the third gate electrode G3, for example.

A lower surface of the third inorganic conductive layer 2300 may be in direct contact with an upper surface of the second portion 115B of the second gate insulating layer 115, and an upper surface of the third inorganic conductive layer 2300 may be in direct contact with a lower surface of the third inter-insulating layer 116. In an embodiment, the entirety of the lower surface of the third inorganic conductive layer 2300 may be in direct contact with the upper surface of the second portion 115B of the second gate insulating layer 115, and the entirety of the upper surface of the third inorganic conductive layer 2300 may be in direct contact with the lower surface of the third inter-insulating layer 116, for example.

Two adjacent fourth inorganic conductive layers 2400 may be arranged between two adjacent subpixel circuits PC, and may be respectively placed on opposite sides of the opening IL-OP of the inorganic insulating layer IL. The fourth inorganic conductive layer 2400 disposed on the left side of the opening IL-OP of the inorganic insulating layer IL and the fourth inorganic conductive layer 2400 disposed on the right side of the opening IL-OP of the inorganic insulating layer IL may include the same material and be disposed on the same layer (e.g., the third inter-insulating layer 116). That is, the fourth inorganic conductive layer 2400 disposed on the left side of the opening IL-OP may be disposed in the same layer as the fourth inorganic conductive layer 2400 disposed on the right side of the opening IL-OP. In an embodiment, each fourth inorganic conductive layer 2400 may include the same material as a first connection metal CM1 to be described below, for example.

A lower surface of the fourth inorganic conductive layer 2400 may be in direct contact with an upper surface of the third inter-insulating layer 116, and an upper surface of the fourth inorganic conductive layer 2400 may be in direct contact with a lower surface of the fourth inter-insulating layer 117. In an embodiment, the entirety of the lower surface of the fourth inorganic conductive layer 2400 may be in direct contact with the upper surface of the third inter-insulating layer 116, and the entirety of the upper surface of the fourth inorganic conductive layer 2400 may be in direct contact with the lower surface of the fourth inter-insulating layer 117, for example.

Two adjacent fifth inorganic conductive layers 2500 may be arranged between two adjacent subpixel circuits PC, and may be respectively placed on opposite sides of the opening IL-OP of the inorganic insulating layer IL. The fifth inorganic conductive layer 2500 disposed on the left side of the opening IL-OP of the inorganic insulating layer IL and the fifth inorganic conductive layer 2500 disposed on the right side of the opening IL-OP of the inorganic insulating layer IL may include the same material and be disposed on the same layer (e.g., the fourth inter-insulating layer 117. That is, the fifth inorganic conductive layer 2500 disposed on the left side of the opening IL-OP may be disposed in the same layer as the fifth inorganic conductive layer 2500 disposed on the right side of the opening IL-OP. In an embodiment, each fifth inorganic conductive layer 2500 may include the same material as a gate signal line GSL to be described below.

A lower surface of the fifth inorganic conductive layer 2500 may be in direct contact with an upper surface of the fourth inter-insulating layer 117, and an upper surface of the fifth inorganic conductive layer 2500 may be in direct contact with a lower surface of the first organic insulating layer 118. In an embodiment, the entirety of the lower surface of the fifth inorganic conductive layer 2500 may be in direct contact with the upper surface of the fourth inter-insulating layer 117, and the entirety of the upper surface of the fifth inorganic conductive layer 2500 may be in direct contact with the lower surface of first organic insulating layer 118, for example.

The conductive inorganic structure 20 including at least one selected from the first to fifth inorganic conductive patterns 2100, 2200, 2300, 2400, and 2500 may form some kind of inorganic wall together with the inorganic insulating layer IL. The conductive inorganic structure 20 and the inorganic insulating layer IL of the inorganic wall may disperse shock applied to the display apparatus 1, and the organic insulating material 118P present between the inorganic walls may have flexibility. Due to the double structure of the inorganic wall and the organic insulating material 118P, the display apparatus 1 may have a structure which may resist an impact but still be transformable (e.g., stretchable).

The signal lines electrically connected to each of the subpixel circuits PC respectively disposed on opposite sides of the opening IL-OP of the inorganic insulating layer IL, e.g., the gate signal lines GSL may be electrically connected by a connection signal line CL. In an embodiment, FIG. 5 illustrates that the gate signal line GSL is disposed on the fourth inter-insulating layer 117. The gate signal line GSL of FIG. 5 may be any one of the first to fourth scan lines SL1, SL2, SL3, and SL4 (refer to FIG. 3) and the emission control line EML (refer to FIG. 3). The gate signal line GSL may be electrically connected to the connection signal line CL through the first connection metal CM1 and a second connection metal CM2 which are arranged under the gate signal line GSL. The connection signal line CL may be disposed in the same layer as a bottom metal layer BML interposed between the substrate 100 and each subpixel circuit PC and may include the same material as that of the bottom metal layer BML. In an embodiment, each of the connection signal line CL and the bottom metal layer BML may include at least one material selected from among aluminum (Al), platinum (Pt), palladium (Pd), silver (Ag), magnesium (Mg), gold (Au), nickel (Ni), neodymium (Nd), iridium (Ir), chrome (Cr), lithium (Li), calcium (Ca), molybdenum (Mo), titanium (Ti), tungsten (W), and copper (Cu), for example.

A connection point for electrical connection between the gate signal line GSL and the connection signal line CL may be disposed on opposite sides of the opening IL-OP of the inorganic insulating layer IL. In this regard, the conductive inorganic structure 20 may be arranged between the connection point for electrical connection between the gate signal line GSL and the connection signal line CL and the opening IL-OP of the inorganic insulating layer IL. In other words, the connection point for electrical connection between the gate signal line GSL and the connection signal line CL may be on a side opposite to the opening IL-OP of the inorganic insulating layer IL with respect to the conductive inorganic structure 20.

Referring to FIG. 5, a first connection point for electrical connection between the gate signal line GSL and the connection signal line CL, which is disposed on the left side of the opening IL-OP, (e.g., a contact point between the at least one gate signal line GSL and the first connection metal CM1, a contact point between the first connection metal CM1 and the second connection metal CM2, and a contact point between the second connection metal CM2 and the connection signal line CL) may be on a side opposite to the opening IL-OP with respect to the conductive inorganic structure 20 arranged on the left side of the opening IL-OP. A second connection point for electrical connection between the gate signal line GSL and the connection signal line CL, which is disposed on the right side of the opening IL-OP, (e.g., a contact point between the at least one gate signal line GSL and the first connection metal CM1, a contact point between the first connection metal CM1 and the second connection metal CM2, and a contact point between the second connection metal CM2 and the connection signal line CL) may be on a side opposite to the opening IL-OP with respect to the conductive inorganic structure 20 arranged on the right side of the opening IL-OP.

The connection signal line CL may overlap the opening IL-OP of the inorganic insulating layer IL and two conductive inorganic structures 20 respectively disposed on opposite sides of the opening IL-OP of the inorganic insulating layer IL.

In some embodiments, the opening IL-OP of the inorganic insulating layer IL may extend to an upper surface of the connection signal line CL. Accordingly, the organic insulating material 118P may be in direct contact with a part of the upper surface of the connection signal line CL through the opening IL-OP.

FIG. 5 illustrates that the second connection metal CM2 is disposed in the same layer as the first semiconductor layer A1 (e.g., disposed on the buffer layer 111) and includes the same material as that of the first semiconductor layer A1, and that the first connection metal CM1 is disposed on the third inter-insulating layer 116 and include the same material as that of the fourth inorganic conductive layer 2400; however, the disclosure is not limited thereto. In another embodiment, the second connection metal CM2 may be disposed in the same layer as the first gate electrode G1 and include the same material as that of the first gate electrode G1. In another embodiment, the second connection metal CM2 may be disposed in the same layer as the second electrode CE2 of the first capacitor Cst and include the same material as that of the second electrode CE2 of the first capacitor Cst. In another embodiment, the second connection metal CM2 may be disposed in the same layer as the upper gate electrode G3b of the third gate electrode G3 and include the same material as that of the upper gate electrode G3b of the third gate electrode G3.

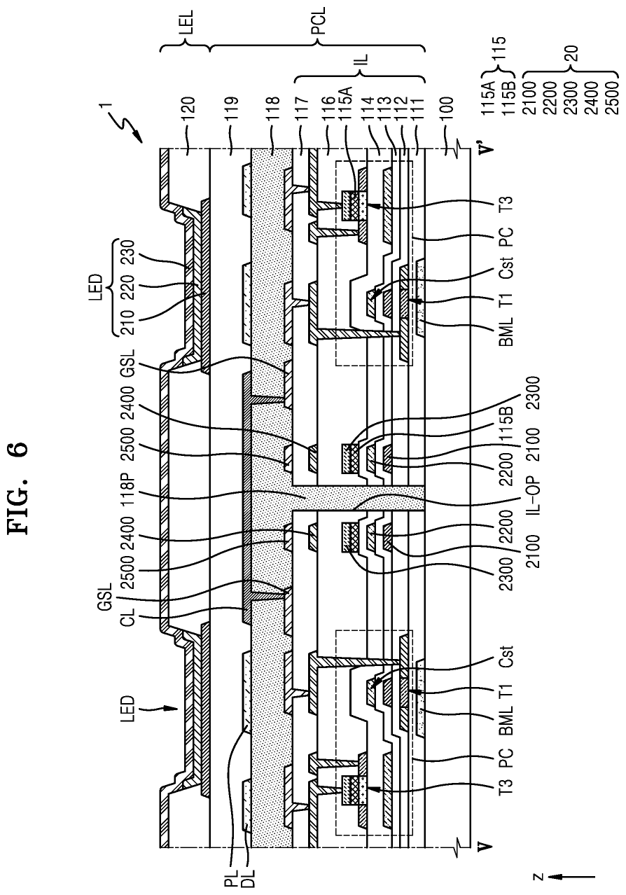

FIG. 6 is a cross-sectional view of an embodiment of the display apparatus 1, taken along line V-V′ of FIG. 4.

According to the display apparatus 1 described above with reference to FIG. 5, the connection signal line CL (refer to FIG. 5) may be disposed in the same layer as the bottom metal layer BML (refer to FIG. 5); however, the disclosure is not limited thereto. In another embodiment, as illustrated in FIG. 6, the connection signal line CL may be disposed on an organic insulating layer between the inorganic insulating layer IL and the light-emitting layer LEL, e.g., the first organic insulating layer 118. Characteristics of the display apparatus 1 other than the position of the connection signal line CL are the same as characteristics of the display apparatus 1 described above with reference to FIG. 5, and thus embodiments will be described focusing on the differences.

The connection signal line CL may be disposed on the first organic insulating layer 118. In some embodiments, the connection signal line CL may include the same material as that of the data line DL and the driving voltage line PL.

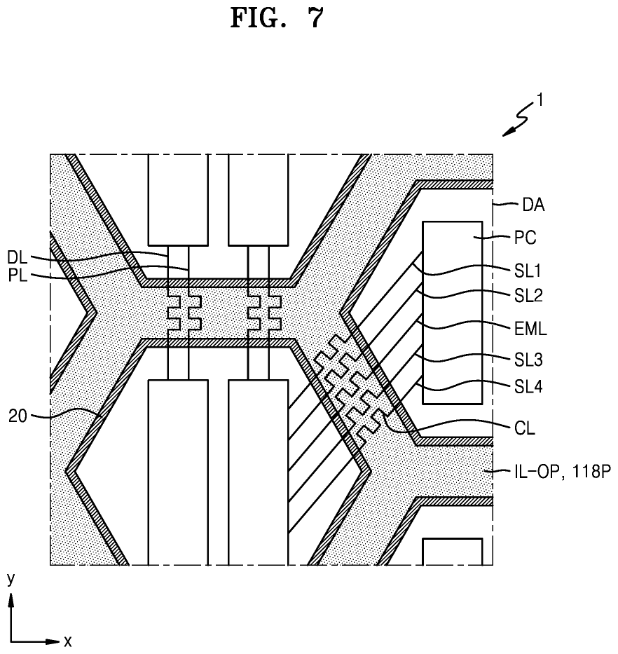

FIG. 7 is a plan view schematically illustrating an embodiment of a part of a display apparatus 1.

A part of each of the data line DL and the driving voltage line PL electrically connected to the subpixel circuit PC surrounded by at least one conductive inorganic structure 20 and the subpixel circuit PC surrounded by another conductive inorganic structure 20, respectively may have a serpentine shape.

Similarly, a part of each of the signal lines electrically connected to the subpixel circuit PC surrounded by at least one conductive inorganic structure 20 and the subpixel circuit PC surrounded by another conductive inorganic structure 20, respectively, e.g., the first to fourth scan lines SL1, SL2, SL3, and SL4 and the emission control line EML (e.g., the connection signal line CL described above with reference to FIG. 6) may have a serpentine shape.

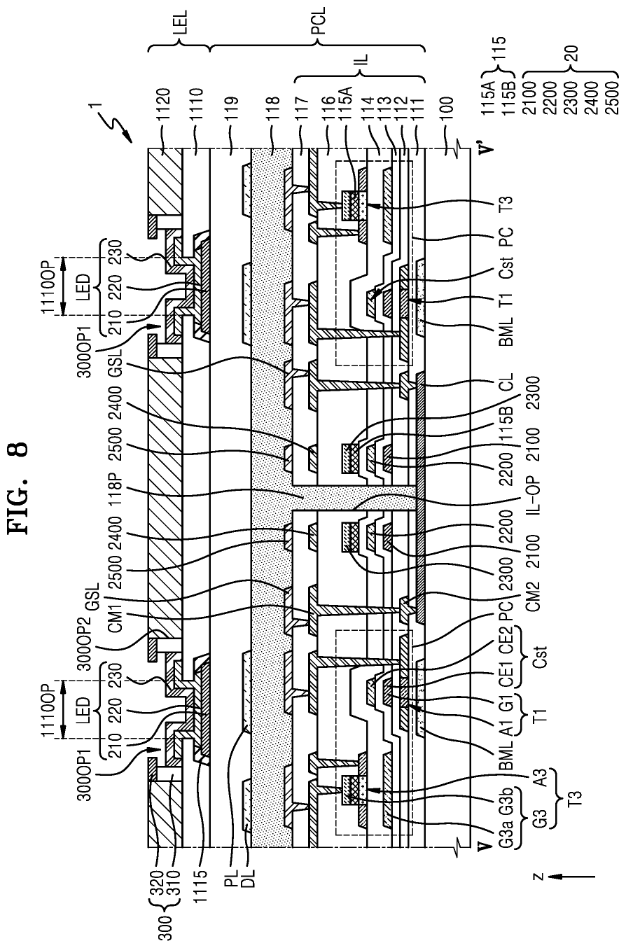

FIG. 8 is a cross-sectional view of an embodiment of the display apparatus 1, taken along line V-V′ of FIG. 4.

According to the display apparatus 1 described above with reference to FIG. 5, the light-emitting diodes LED (refer to FIG. 5) of the light-emitting layer LEL (refer to FIG. 5) may share the second electrode 230 (refer to FIG. 5); however, the disclosure is not limited thereto. In another embodiment, as illustrated in FIG. 8, each of the light-emitting diodes LED of the light-emitting layer LEL may include the second electrode 230 having an isolated shape. Characteristics of the display apparatus 1 other than the structure of the light-emitting layer LEL are the same as characteristics of the display apparatus 1 described above with reference to FIG. 5, and thus embodiments will be described focusing on the differences.

Each light-emitting diodes LED may include the first electrode 210, the light-emitting layer 220, and the second electrode 230, and an edge of the first electrode 210 may be covered by a conductive protection layer 1115. The conductive protection layer 1115 may include at least one conductive oxide selected from among indium tin oxide (“ITO”), indium zinc oxide (“IZO”), indium gallium zinc oxide (“IGZO”), indium tin zinc oxide (“ITZO”), zinc oxide (ZnO), aluminum doped zinc oxide (“AZO”), gallium doped zinc oxide (“GZO”), zinc tin oxide (“ZTO”), gallium tin oxide (“GTO”), and fluorine doped tin oxide (“FTO”).

An insulating bank layer 1110 may be disposed on the conductive protection layer 1115 and the second organic insulating layer 119. The insulating bank layer 1110 may define an opening 1110OP overlapping a central area of the first electrode 210. The insulating bank layer 1110 may include an inorganic insulating material.

A conductive bank layer 300 may be disposed on the insulating bank layer 1110. The conductive bank layer 300 may include conductive layers having different etch rates from each other. In an embodiment, the conductive bank layer 300 may include a first conductive layer 310 and a second conductive layer 320 disposed on the first conductive layer 310. The first conductive layer 310 and the second conductive layer 320 may include metals having different etch rates from each other. In an embodiment, the first conductive layer 310 may be a layer including aluminum (Al) and the second conductive layer 320 may be a layer including titanium (Ti). A part of the second conductive layer 320 may protrude towards a first opening 300OP1 from a contact point between a lower surface of the second conductive layer 320 and a lateral surface of the first conductive layer 310, and accordingly, the conductive bank layer 300 may have an overhang structure (or an eaves structure).

The conductive bank layer 300 may define the first opening 300OP1 overlapping the opening 1110OP of the insulating bank layer 1110. Through the first opening 300OP1 of the conductive bank layer 300 and the opening 1110OP of the insulating bank layer 1110, the light-emitting layer 220 may be deposited on the first electrode 210, and the second electrode 230 may be deposited on the light-emitting layer 220. An edge of the second electrode 230 may be in direct contact with the lateral surface of the conductive bank layer 300, e.g., the lateral surface of the first conductive layer 310 directed towards the first opening 300OP1.

The conductive bank layer 300 may define a second opening 300OP2 arranged between adjacent light-emitting diodes LED. An organic material 1120 may be arranged in the second opening 300OP2 of the conductive bank layer 300. The organic material 1120 may include an organic insulating material, for example.

In an embodiment of the disclosure, provided is a stretchable display apparatus which may resist an impact but still be transformable.

It should be understood that embodiments described herein should be considered in a descriptive sense only and not for purposes of limitation. Descriptions of features or advantages within each embodiment should typically be considered as available for other similar features or advantages in other embodiments. While embodiments have been described with reference to the drawing figures, it will be understood by those of ordinary skill in the art that various changes in form and details may be made therein without departing from the spirit and scope as defined by the following claims.

What is claimed is:

1. A stretchable display apparatus comprising:
a substrate;
a circuit layer disposed on the substrate and including a first subpixel circuit and a second subpixel circuit, the circuit layer comprising:
a plurality of inorganic insulating layers including a first inorganic insulating layer and a second inorganic insulating layer; and
a first inorganic conductive pattern and a second inorganic conductive pattern interposed between the first inorganic insulating layer and the second inorganic insulating layer; and
a light-emitting layer disposed on the circuit layer and including a first light-emitting diode electrically connected to the first subpixel circuit and a second light-emitting diode electrically connected to the second subpixel circuit,
wherein the plurality of inorganic insulating layers is interposed between the substrate and the light-emitting layer,
an opening passing through the first inorganic insulating layer and the second inorganic insulating layer is defined in the plurality of inorganic insulating layers in an area between the first subpixel circuit and the second subpixel circuit, and
the first inorganic conductive pattern and the second inorganic conductive pattern are disposed between the first subpixel circuit and the second subpixel circuit and respectively disposed on opposite sides of the opening.

2. The stretchable display apparatus of claim 1, wherein each of a lower surface of the first inorganic conductive pattern and a lower surface of the second inorganic conductive pattern is in direct contact with an upper surface of the first inorganic insulating layer, and
each of an upper surface of the first inorganic conductive pattern and an upper surface of the second inorganic conductive pattern is in direct contact with a lower surface of the second inorganic insulating layer.

3. The stretchable display apparatus of claim 1, wherein the first inorganic conductive pattern has a closed-loop shape surrounding an entirety of the first subpixel circuit in a plan view, and
the second inorganic conductive pattern has a closed-loop shape surrounding an entirety of the second subpixel circuit in the plan view.

4. The stretchable display apparatus of claim 3, wherein each of the closed-loop shape of the first inorganic conductive pattern and the closed-loop shape of the second inorganic conductive pattern is a polygonal shape or a circular shape.

5. The stretchable display apparatus of claim 1, wherein the circuit layer further comprises an organic insulating layer interposed between the plurality of inorganic insulating layers and the light-emitting layer, and
a part of the organic insulating layer at least partially fills the opening of the plurality of inorganic insulating layers.

6. The stretchable display apparatus of claim 5, further comprising:
a first signal line electrically connected to the first subpixel circuit;
a second signal line electrically connected to the second subpixel circuit; and
a connection signal line connecting the first signal line to the second signal line,
wherein the connection signal line overlaps the opening of the plurality of inorganic insulating layers, the first inorganic conductive pattern, and the second inorganic conductive pattern.

7. The stretchable display apparatus of claim 6, wherein a first connection point for electrical connection between the first signal line and the connection signal line is disposed on a side opposite to the opening of the plurality of inorganic insulating layers with respect to the first inorganic conductive pattern disposed between the first connection point and the opening, and
a second connection point for electrical connection between the second signal line and the connection signal line is disposed on a side opposite to the opening of the plurality of inorganic insulating layers with respect to the second inorganic conductive pattern disposed between the second connection point and the opening.

8. The stretchable display apparatus of claim 6, further comprising a bottom metal layer interposed between the substrate and the first subpixel circuit or between the substrate and the second subpixel circuit,
wherein the connection signal line is disposed in a same layer as the bottom metal layer and includes a same material as a material of the bottom metal layer.

9. The stretchable display apparatus of claim 8, wherein the opening of the plurality of inorganic insulating layers extends to an upper surface of the connection signal line.

10. The stretchable display apparatus of claim 6, wherein the connection signal line is disposed on the organic insulating layer.

11. The stretchable display apparatus of claim 6, wherein the connection signal line has a serpentine shape in a plan view.

12. A stretchable display apparatus comprising:
a substrate;
a circuit layer disposed on the substrate and including a first subpixel circuit and a second subpixel circuit, the circuit layer comprising:
a plurality of inorganic insulating layers;
a first inorganic conductive pattern surrounding the first subpixel circuit in a plan view; and
a second inorganic conductive pattern disposed adjacent to the first inorganic conductive pattern and surrounding the second subpixel circuit in the plan view; and
a light-emitting layer disposed on the circuit layer and including a first light-emitting diode electrically connected to the first subpixel circuit and a second light-emitting diode electrically connected to the second subpixel circuit,
wherein the plurality of inorganic insulating layers is interposed between the substrate and the light-emitting layer.

13. The stretchable display apparatus of claim 12, wherein the plurality of inorganic insulating layers includes a first inorganic insulating layer and a second inorganic insulating layer,
each of a lower surface of the first inorganic conductive pattern and a lower surface of the second inorganic conductive pattern is in direct contact with an upper surface of the first inorganic insulating layer, and
each of an upper surface of the first inorganic conductive pattern and an upper surface of the second inorganic conductive pattern is in direct contact with a lower surface of the second inorganic insulating layer.

14. The stretchable display apparatus of claim 12, wherein the plurality of inorganic insulating layers has a mesh structure in the plan view and include an opening at least partially filled with an organic insulating material, and
a part of the opening is disposed in an area between the first inorganic conductive pattern and the second inorganic conductive pattern.

15. The stretchable display apparatus of claim 14, further comprising:
a first signal line electrically connected to the first subpixel circuit;
a second signal line electrically connected to the second subpixel circuit; and
a connection signal line connecting the first signal line to the second signal line,
wherein the connection signal line overlaps the opening of the plurality of inorganic insulating layers, the first inorganic conductive pattern, and the second inorganic conductive pattern.

16. The stretchable display apparatus of claim 15, wherein a first connection point for electrical connection between the first signal line and the connection signal line is disposed on a side opposite to the opening of the plurality of inorganic insulating layers with respect to the first inorganic conductive pattern disposed between the first connection point and the opening, and
a second connection point for electrical connection between the second signal line and the connection signal line is disposed on a side opposite to the opening of the plurality of inorganic insulating layers with respect to the second inorganic conductive pattern disposed between the second connection point and the opening.

17. The stretchable display apparatus of claim 16, further comprising a bottom metal layer interposed between the substrate and the first subpixel circuit or between the substrate and the second subpixel circuit,
wherein the connection signal line is disposed in a same layer as the bottom metal layer and includes a same material as a material of the bottom metal layer.

18. The stretchable display apparatus of claim 17, wherein the opening of the plurality of inorganic insulating layers extends to an upper surface of the connection signal line.

19. The stretchable display apparatus of claim 16, further comprising an organic insulating layer including the organic insulating material,
wherein the connection signal line is disposed on the organic insulating layer.

20. The stretchable display apparatus of claim 15, wherein the connection signal line has a serpentine shape in the plan view.
